(19) United States
(12) Patent Application Publication
(10) Pub. No.: US 2009/0091337 A1
(43) Pub. Date: Apr. 9, 2009

(54) CARBON FILM COMPOSITE, METHOD OF MANUFACTURING A CARBON FILM COMPOSITE AND SENSOR MADE THEREWITH

(76) Inventors: Joshua A. Robinson, Spring Mills, PA (US); Eric S. Snow, Springfield, VA (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 11/867,093

(22) Filed: Oct. 4, 2007

(51) Int. Cl. G01N 27/04; C23C 16/26

(52) U.S. Cl. 324/693; 427/249.1; 252/502; 977/843

(57) ABSTRACT

Manufacturing a carbon film composite including depositing a carbon film layer onto a substrate, depositing a catalyst suitable for catalyzing the growth of carbon nanotubes onto the carbon film layer and heating in the presence of a carbon-source gas in a substantially inert environment. A carbon film composite featuring a carbon film layer deposited onto a substrate. The carbon film layer has an active surface that is electrically sensitive to the presence of target chemicals. A chemical sensor featuring such a carbon film composite that also includes a first electrode and a second electrode in electrical contact with an active surface of the carbon film composite and a resistivity monitoring device connected to the first and second electrodes. A method of sensing a target chemical featuring exposing such a carbon film composite to a target chemical and recording a change in resistivity across the carbon film composite.

### FIELD OF THE INVENTION

The present invention is generally directed to a carbon film composite, a method of making the carbon film composite and a sensor made from the carbon film composite.

### BACKGROUND OF THE INVENTION

Due to recent world events and associated terror activities throughout the world, new techniques for detecting low concentrations of potentially hazardous materials, such as explosives, toxic chemicals, nerve agents or biomolecules (all examples of “target chemical” for which detection thereof may be of particular interest). Detection of certain target chemicals, in liquid and vapor environments are desirable for use in defense, security and environmental monitoring applications. Also, chemical detection has also been used in a variety of biological and biotechnical applications as well. It is particularly desirable to have the ability to sense target chemicals at concentrations as low as 0.01 to 1.0 parts-per-billion (ppb). For use in public spaces and/or under battlefield conditions, sensors that use minimal power and are very small and compact in size are of particular interest.

Metal oxides and/or polymer composites are currently being used as transducers in microelectronic sensors. The metal oxides and/or polymer composites provide a change in electrical property upon adsorption of a particular class of target chemicals. An electrical signal is developed by measuring the change in an electrical property of the metal oxide or polymer, such as resistance or capacitance, when the metal oxides and/or polymer composite is in the presence of a target chemical and transmitting that electrical signal to a microprocessor.

In operation, a target chemical molecule must diffuse through the metal oxide and/or polymer composite in order to produce a maximum signal. Thus, such sensors are able to sense only as low as about 10 ppb. In addition, they generally have a response time of about 1 minute, which often includes the additional step of removing the target chemical from the sensor to prepare for the next sensing operation. The generally slow response time also is attributed to the time required to load the active sensor material with a sufficient quantity of chemical selective analyte. Further, these transducer elements may suffer from poor target chemical adhesion and instability.

Surface-sensitive transducers have been developed that reduce the amount of a target chemical required for sensing by eliminating the need for a chemical selective analyte. For example, microelectronic sensors have been made with random networks of carbon nanotubes grown on a substrate. See U.S. Patent Application Publication No. 2006/0249402, published Nov. 9, 2006, which is incorporated herein by reference in its entirety. These carbon nanotube transducers operate by exhibiting a change in resistance caused by certain molecules being adsorbed on the carbon nanotube surfaces. In particular, upon adsorption of target chemical molecules, a measurable charge transfer occurs on the carbon nanotube surface. Carbon nanotube transducers are prepared by growing random networks of carbon nanotubes, using conventional carbon nanotube microfabrication techniques, onto the surface of a dielectric material substrate. However, in experiencing random charge fluctuations by the adsorption of molecules, these sensors suffer from low-frequency noise. Also, the dielectric substrate often used is hydrophilic. Thus, carbon nanotube sensors often suffer from electrical response fluctuations based on the level of ambient humidity, which can lead to inaccurate sensing in variable humidity environments.

### BRIEF SUMMARY OF THE INVENTION

The present application is generally directed to a carbon film composite, a method for manufacturing the carbon film composite and a sensor that incorporates the carbon film composite. The carbon film composite of the present invention has distinct advantages over the use of mere carbon nanotube networks for sensing applications in particular. For example, carbon film composite sensors of the present invention experience increased sensitivity, low-noise and do not suffer from variable humidity conditions.

One aspect of the present invention is a method of manufacturing a carbon film composite that includes providing a substrate, depositing a carbon film layer onto the substrate and depositing a catalyst onto the carbon film layer to form a catalyst-treated carbon film layer. The catalyst is suitable for catalyzing the growth of carbon nanotubes. The catalyst-treated carbon film layer is then heated in the presence of a carbon-source gas in a substantially inert environment. Carbon nanotubes may or may not be grown on the surface of the carbon film layer by this process.

Another aspect of the present invention is a composite material featuring a substrate and a carbon film layer deposited onto the substrate. The carbon film layer has an active surface that is electrically sensitive to the presence of target chemicals.

Another aspect of the present invention is a chemical sensor including a carbon film composite. The carbon film composite has a substrate and a carbon film layer applied to the substrate. The carbon film layer is treated with a catalyst and heated in the presence of a carbon source gas in a substantially inert environment. The chemical sensor also includes a first electrode in electrical contact with an active surface of the carbon film composite, a second electrode in electrical contact with the active surface of the carbon film composite, and a resistivity monitoring device electrically connected to the first and second electrodes.

Another aspect of the present invention is a method of sensing a target chemical that includes providing a chemical sensor incorporating a carbon film composite. The carbon film composite has a carbon film layer applied to a substrate that is treated with a catalyst and heated in the presence of a carbon source gas in a substantially inert environment. The carbon film composite is exposed to a target chemical and a change in resistivity across the carbon film composite is recorded for the target chemical.

The foregoing and other features and advantages of the present invention will be apparent from the following, more particular description of a preferred embodiment of the invention, as illustrated in the accompanying drawings.

### BRIEF DESCRIPTION OF THE DRAWINGS

FIG. 1 is a scanning electron micrograph (SEM) of a carbon film layer of an example of a carbon film composite of the present invention.

FIG. 2 is a SEM of an example of a carbon film composite of the present invention manufactured with an intermediate flow rate of a carbon source gas.

FIG. 3 is a graphical representation of the response of sensors made from examples of three carbon film composites of the present invention as compared to the response of a sensor made from a conventional carbon nanotube transducer.

FIG. 4 is a graphical representation of the response of an example of a carbon film composite of the present invention at five different relative humidity levels between 0 and 80% humidity.

FIG. 5 is a SEM of an example of a carbon film composite of the present invention manufactured with a low flow rate of a carbon source gas.

FIG. 6 is a SEM of an example of a carbon film composite of the present invention manufactured with an intermediate flow rate of a carbon source gas but demonstrating little or no carbon nanotube growth.

FIG. 7 is a SEM of an example of a carbon film composite of the present invention manufactured with a high flow rate of a carbon source gas.

FIG. 8 is a conventional scheme for functionalizing carbon nanotubes.

FIG. 9 is a schematic of a sensor incorporating a carbon film composite of the present invention.

FIG. 10 is a noise-power spectrum of a conventional pure carbon nanotube network and a carbon film composite of the present invention.

### DETAILED DESCRIPTION OF THE INVENTION

Preferred embodiments of the present invention are now described with reference to the Figures, in which like reference numerals are generally used to indicate identical or functionally similar elements. Also in the Figures, the left most digit of each reference numeral generally corresponds to the Figure in which the reference numeral appears. While specific details of the preferred embodiments are discussed, it should be understood that this is done for illustrative purposes only. A person skilled in the relevant art will recognize that other configurations and arrangements can be used without departing from the spirit and scope of the invention. It will also be apparent to a person skilled in the relevant art that aspects of the present invention can also be employed in other applications.

The carbon film composite of the present invention provides increased performance over pure networks of carbon nanotube in sensing applications. The carbon film composite generally includes a thin carbon film layer deposited onto a substrate layer. The carbon film composite further includes treating the carbon film layer such that the carbon film composite has an active surface that is electrically sensitive to the presence of certain target chemicals. This active surface may include the growth of carbon nanotubes onto the carbon film layer. However, a carbon film composite of the present invention may alternatively include an active surface which is merely a carbon film layer which has undergone this treatment, whether or not carbon nanotubes are actually grown on the carbon film layer. The carbon film composite experiences a measurable change in resistivity upon the presence of selective target chemicals which can be converted into an electrical signal. Meanwhile, a carbon film layer without such treatment does not demonstrate any significant measurable change in resistivity. Thus, the carbon film composite of the present invention generally includes a substrate and a carbon film layer which has undergone this particular treatment and has an active surface that is electrically sensitive to the presence of target chemicals.

Generally, this treatment includes depositing a catalyst onto the carbon film layer. Preferably, the catalyst is one that is suitable for catalyzing the growth of carbon nanotube. The carbon film composite then is heated in an inert environment. A carbon-source gas is flowed across the catalyst-treated carbon film layer. The composite is then cooled to room temperature. Depending upon the flowrate of the carbon source gas and/or other processing conditions, carbon nanotubes may not grow on the carbon film layer, a partial growth of carbon nanotubes may become apparent on the surface of the carbon film layer, or a network of carbon nanotubes are clearly present across the surface of the carbon film layer. Despite the presence or absence of the carbon nanotube, these carbon film composites having undergone this treatment demonstrate measurable sensitivity to the presence of selective target chemicals and an increase in sensitivity over pure networks of carbon nanotubes.

Sensors made from the carbon film composite of the present invention exhibits three distinct advantages over pure carbon nanotube sensors including increased signal, decreased noise and reduced humidity sensitivity. For a broad range of target chemicals, the relative change in resistivity response of the carbon film composite is up to an order of magnitude better than the response of comparable pure carbon nanotube networks. The partially-conductive carbon film layer protects the active surface of the carbon film composite that experiences the change in resistivity from charge fluctuations that occur in the underlying dielectric substrate. Consequently, the noise performance of the carbon film composite of the present invention is improved over pure carbon nanotube networks grown directly onto a dielectric substrate. Thus, the ability to detect target chemicals at a concentration of at least as low as 1 ppb has been demonstrated, and concentrations as low as 1 part-per-million (ppm) or 100 parts-per-thousand (ppt) and possibly lower are anticipated.

Further, conventional carbon nanotube networks are typically grown a silicon (Si) or silicon oxide (SiO₂) substrate that is hydrophilic. This hydrophilic substrate increases the effects of ambient humidity on the sensor's performance. In contrast, the carbon film layer of the carbon film composite is hydrophobic, even with the use of a hydrophilic substrate. Thus, the carbon film layer protects the active surface of the carbon film composite from humidity effects on the substrate. Consequently, a sensor utilizing the carbon film composite will have a response that is less effected by ambient humidity.

### EXAMPLE 1

Examples of carbon film composites of the present invention were made by the following method.

### Application of a Thin Carbon Film Layer to a Substrate

A thin carbon film layer was deposited onto a substrate. Although a Si/SiO₂ wafer was chosen for the substrate in this example, one skilled in the art can appreciate any type of substrate may be suitable for use with the present invention. For many applications, a dielectric substrate is preferable since it insulates surrounding components from the electrical activity of the active surface of the carbon film composite of the present invention, particularly when used as a transducer for electrical applications such as in a microelectronic sensor.

In this example, the carbon film layer was carbonized from a commercial Novalak resist (1805 Resist commercially available from Shipley) that was spin coated onto the substrate. The Novalak resist is an example of a high-carbon content polymer. One skilled in the art can appreciate that other carbon-containing polymers, particularly high-carbon content polymers, may be equally suitable for use during such a carbonization process. In this Example, the Novalak resist used was diluted to various ratios with Type P Thinner and spun onto the substrate at 6000 RPM for 30 seconds.

Carbonization of the carbon-containing polymer causes the removal of solvents and/or other non-carbon components leaving a carbon film layer disposed on the substrate. In this Example, carbonization includes preheating a tube furnace to about 1000° C. under flowing Argon (Ar). Flowing hydrogen (H₂) was then added to equilibrate the environment of the furnace for about a minute. Resist-coated wafers were then added to the furnace and held at about 1000° C. for about 15 minutes. The carbon film layer was then cooled in the furnace.

FIG. 1 is a scanning electron micrograph (SEM) of the carbon film layer formed in this Example. The Novalak resist has demonstrated about an 80% carbon film yield using the methods discussed above. The rapid heating of the carbonization process causes a surface porosity where solvents of the resist have been eliminated leaving only the carbon film layer. In FIG. 1, the darker areas of the carbon film layer are the pores. Preferably, the carbon film layer has some porosity or unstructured texture to it, such that the thin carbon film layer does not function like that of a solid metal sheet. The porosity or unstructured texture provides an increased surface area, which provides contact for adsorption of particular target chemicals and contact with a catalyst during the treatment of the thin carbon film layer discussed below.

The porosity and/or unstructured texture of the carbon film layer can be optimized by altering the carbonization process. For example, in an alternative method, the resist-coated wafer was placed on a hot plate at about 100° C. for about 5 minutes. The resist coated wafer was then placed in a tube furnace at room temperature with a flowing Ar/H₂ gas mix. The furnace was then heated to about 300° C. and maintained for about 45 minutes. The furnace was then heated to about 1000° C. and held for about 45 minutes. The furnace was then allowed to cool to room temperature while maintaining the Ar/H₂ gas flow. One skilled in the art can optimize the porosity and/or unstructured texture of the carbon film layer of the present invention by routine experimentation with a carbonization process.

Further, the furnace could be alternative sizes or shapes or heated to alternative temperatures, such as between 500 and 1500° C., preferably 800-1000° C., with varying but acceptable carbonization results. Alternatively, methods other than carbonizing a carbon-containing polymer may be used to form a carbon film layer on a substrate. Some non-limiting examples of other methods include sputter deposition, chemical vapor deposition or pulse laser deposition of carbon onto a substrate.

Preferably, the carbon film layer has a thickness of less than 100 angstroms, more preferably less than 30 angstroms. As such, using the carbonizing methods described above, it is preferred that the thickness of the carbon-containing polymer is such to produce a carbon film layer of desired thickness. One skilled in the art would appreciate that the thickness of the carbon-containing polymer may be much thicker than the resulting carbon film layer depending upon the particular method of carbonization and type of carbon-containing polymer used.

Once formed, the carbon film layer can optionally be checked for conductivity. Preferably, the thin carbon film has a resistivity of about 1 kilo-ohm per square (k-Ω/sq) or higher, more preferably about 20 k-Ω/sq or higher. One skilled in the art can appreciate that conductivity of the carbon film layer can be optimized. For example, altering the temperature, size or shape of the furnace during carbonization (for example, generally higher temperatures cause lower resistivity), the type of carbon-containing polymer used, and the thickness of the carbon-containing polymer may be used to change and/or optimize conductivity of the thin carbon film layer for a particular activity.

### Treatment of Thin Carbon Film Layer

Prior to the following treatment, the resistivity of the carbon film layer is not measurably sensitive to target chemicals, and the carbon film layer is less resistive than the active surface of the carbon film composite after the thin carbon film layer has been treated as discussed below.

A catalyst, in this Example ferric nitrite, and propanol were mixed in about a 25 mg/75 ml weight/volume ratio for about 30 minutes. The substrate and the carbon film layer were dipped into the mixture for about 15 seconds, rinsed with hexane and dried in a nitrogen gas stream. The wafer was placed into a tube furnace at room temperature with a flowing Ar/H₂ gas mix in about a 600:400 volume ratio. After waiting for about 5 minutes for the flowing Ar/H₂ gas mix to purge air from the furnace, the furnace was heated to about 800° C. When the temperature stabilized at 800° C., an ethylene gas flow was added to the furnace for about 20 minutes. The ethylene flow was turned off and the furnace was allowed to cool to room temperature under the continued flowing Ar/H₂ gas mixture.

Although one method has been described in this example, one skilled in the art can appreciate that the general method may be optimized by varying different aspects of the method. For example, ferric nitrite was used as a liquid catalyst in this example. However, a variety of catalysts are known in the art for the formation of carbon nanotubes. One skilled in the art can also appreciate that any alternative carbon nanotube producing catalysts could be used in the present invention and that some alternative catalysts may be particularly suitable for particular applications of the carbon film composite. Such catalysts are not always liquid and may be deposited using methods other than dip-coating. One non-limiting example of an alternative catalyst is the deposition of a thin film of iron, for example less than 10 angstroms thick, which may be deposited by methods such as precipitating iron from a iron containing solution, evaporating or sputter deposition. Also, it would be apparent to one skilled in the art that the substantially inert environment created by the Ar/H₂ gas mixture may be created using alternative inert gases, such as nitrogen, rather than Argon. Also, the substantially inert environment created by the Ar/H₂ gas mixture may be provided at alternative flow rates. Hydrogen may also be substituted for an alternative gas and/or at an alternative flow rate that will burn off oxygen from the carbon film layer and the environment. Similarly, the size, shape and temperature of the furnace may be optimized for a particular application. For example, the furnace could be heated to alternative temperatures, such as between 500 and 1500° C., preferably 800-1000° C., with varying but acceptable treatment results.

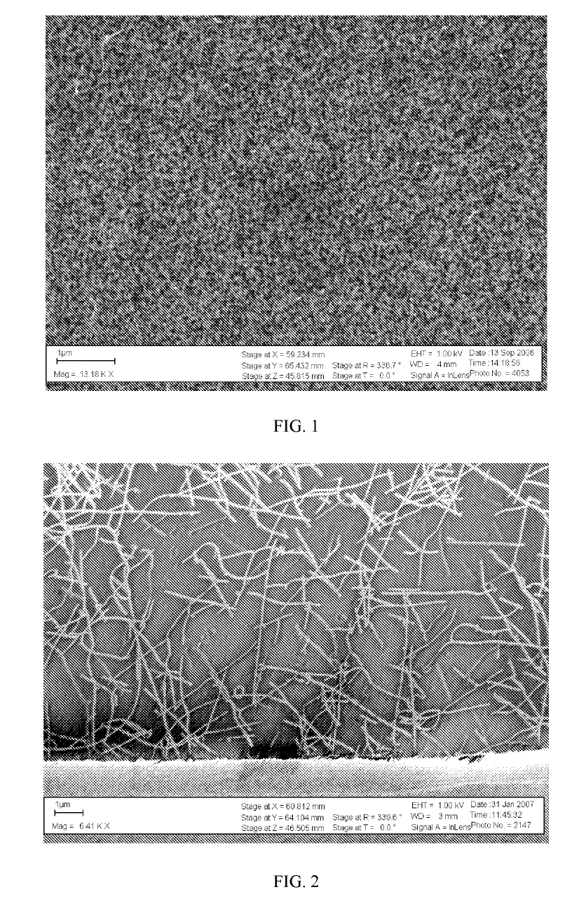

While ethylene gas was used as a carbon-source gas in this Example, one skilled in the art will appreciate that any high carbon-source gas may be used in the present invention, particularly any pure hydrocarbon gases, such as methanol, methylene, propylene, etc. In this Example, the carbon film composite consists of carbon nanotubes grown on top of the carbon film layer. The carbon-source gas was flowed through the furnace at an intermediate rate, for example greater than about 2-3 standard cubic centimeters per minute (SCCM), or about 5 SCCM. FIG. 2 is a SEM showing carbon nanotubes grown on the carbon film layer. Testing the resistivity of the carbon film composite

### EXAMPLE 2

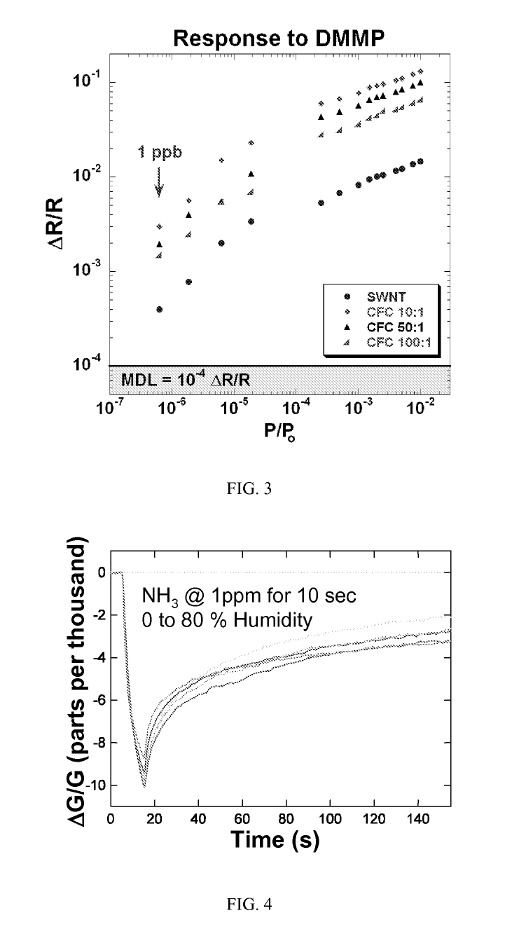

The general method described above causes a slight change in electron concentration on the surface of the carbon film composite. As target chemical molecules are absorbed onto the active surface of the carbon film composite, a change in charge occurs, which leads to a measurable change in the resistivity of the carbon film composite. The carbon film composite of the present invention has demonstrated up to one order of magnitude increase in the relative resistivity response to the presence of many chemical vapors over conventional carbon nanotube networks. FIG. 3 illustrates the relative change in resistivity response to the presence of various concentrations of DMMP (a chemical which is often used to simulate hazardous nerve agents) of a sensors made from three different carbon film composites of Example 1 (diamonds and triangles). FIG. 3 also compares the sensors of the present invention to a conventional single-walled nanotube sensor (circles). As the relative change in resistivity is measured on a logarithmic scale, the best results provide about an order of magnitude increase in response sensitivity over the convention pure single-walled nanotube sensor. The data in FIG. 3 was designed to gauge optimal dilution of the Novalak resist in propanol in Example 1. The data shows that higher concentrations of the Novalak resist (e.g., in a 10 to 1 ratio) provided better sensing results than lower concentrations. FIG. 3 also illustrates that each sensor made from the carbon film composite of the present invention is able to provide a significantly increased response over the pure carbon nanotube sensor with target chemical concentrations as low a 1 ppb.

Meanwhile, the level of 1/f noise was decreased by a factor of 2 or more over conventional carbon nanotube networks. FIG. 10 is a 1/f noise-power spectrum 1002 of a conventional pure carbon nanotube network and a 1/f noise-power spectrum 1004 a carbon film composite of the present invention. The pure carbon nanotube network use for this noise study had comparable film resistivity to the carbon film composite used for this noise study. As illustrated in FIG. 10, the carbon film composite of the present invention exhibits less noise-power than the conventional pure carbon nanotube network by a factor of about 10.

The net result of the increased sensitivity and decreased noise is a resistivity response in the composite films that produces a higher signal-to-noise ratio than that of conventional carbon nanotube networks.

### EXAMPLE 3

FIG. 4 shows the response of a sensor made with a carbon film composite of Example 1 to 1 ppm ammonia (NH₃) delivered in air in 5 second doses of with humidity ranging from 0 to 80%. Note that the response, here relative change in conductivity, is relatively insensitive to the level of ambient humidity. Meanwhile, the response of conventional pure carbon nanotube sensors is known to vary dramatically with the level of ambient humidity, particularly when used in ammonia sensing applications.

### Altering the Flow Rate of the Carbon-Source Gas and Its Effect on Carbon Nanotube Growth

### EXAMPLE 4

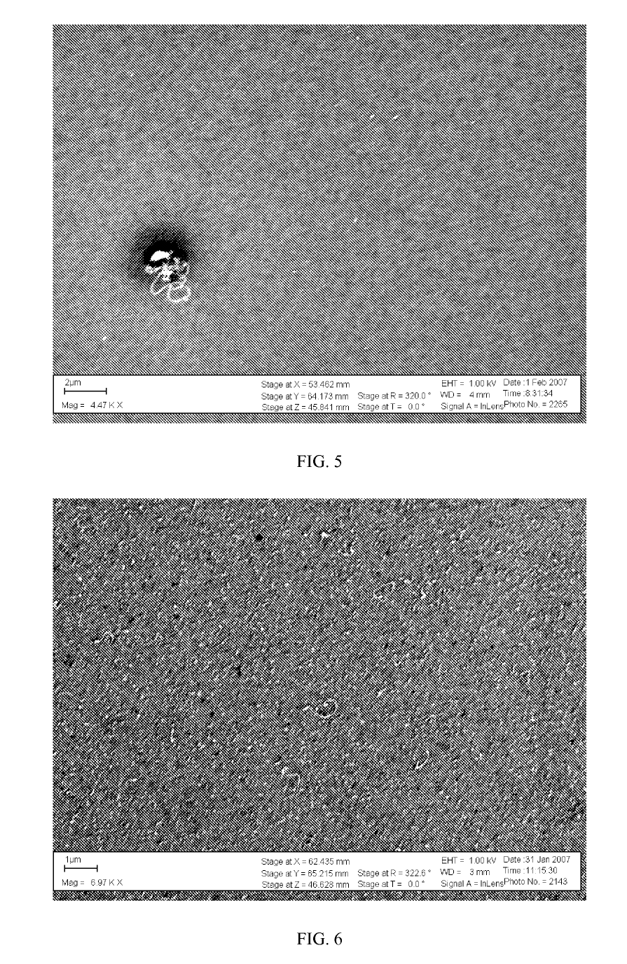

Another alternative to the method described in Example 1 is to alter to the flow rate of the carbon-source gas to control the growth of carbon nanotube on the carbon film layer. FIG. 5 is a SEM of a carbon film composite made by the method of Example 1. However, the carbon-source gas was flowed into the tube furnace at a very low flow rate, particularly about 0.5 SCCM or about an order of magnitude lower than that of the Example of FIG. 2. In FIG. 5, carbon nanotubes are not visibile on the carbon film composite. While the carbon film composite of FIG. 5 has demonstrated about 2-3 times less responsiveness as compared to the carbon film composite made at an intermediate flow rate, the carbon film composite example of FIG. 5 still demonstrates enhanced sensitivity over pure carbon nanotube growth. Further, the carbon film composite of FIG. 5 has demonstrated increased noise reduction over the carbon film composite of FIG. 2 on which the growth of carbon nanotubes are readily visible.

Thus, it is the treatment of the carbon film layer and not the actual growth of carbon nanotubes on the active surface of a carbon film composite of the present invnetion that causes the carbon film composite to have an increased response to target chemicals. It is important to note that a carbon film layer without such treatment does not exhibit any measurable sensitivity to target chemicals.

### EXAMPLE 5

FIG. 6 is an SEM of another carbon film composite made by the method of Example 1. In this Example, the carbon-source gas was flowed into the furnace at an intermediate flow rate substantially similar to that of FIG. 2 and under substantially similar conditions. However, little if any growth of carbon nanotubes are visible on the surface of the carbon film layer in FIG. 6. Many factors may explain why when treated under substnatially similar conditions, growth of carbon nanotubes may differ between samples, such as position within the furnance and exposure to heat, the inert environment and/or the carbon-source gas, all of which may be optimized to achieve a preferred growth of carbon nanotubes, if desired. Even with little or no carbon nanotube growth, the carbon nanotubes of FIG. 2 provide an substnatially similar increase in response to target chemicals and reduction of noise as the carbon film composite of FIG. 2 over conventional carbon nanotubes sensors.

### EXAMPLE 6

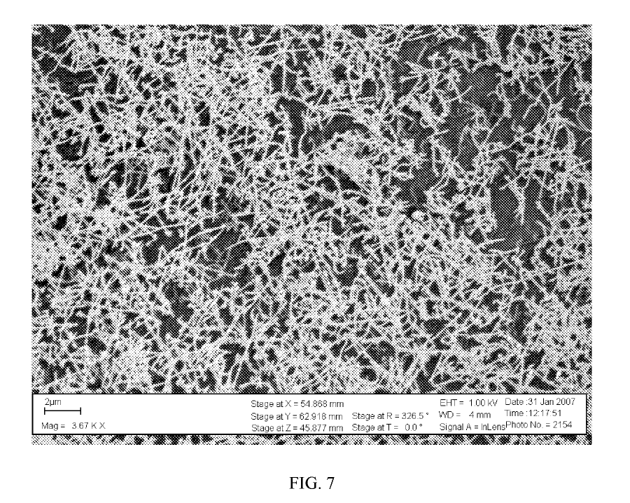

FIG. 7 is an SEM of another carbon film composite made by the method of Example 1. However, the carbon-source gas in this Example was flowed into the furnace at a very high flow rate, particularly about 50 SCCM or about an order of magnitude higher than that of the carbon film composites of FIGS. 2 and 6. As seen in FIG. 7, a very thick growth of carbon nanotubes are visible on the surface of the carbon film layer. While the carbon film composite of FIG. 7 demonstrates about 2-3 times less responsiveness as compared to the carbon film composite made at an intermediate flow rate, the carbon film composite example of FIG. 7 still demonstrates enhanced sensitivity over pure carbon nanotube growth.

### EXAMPLE 7

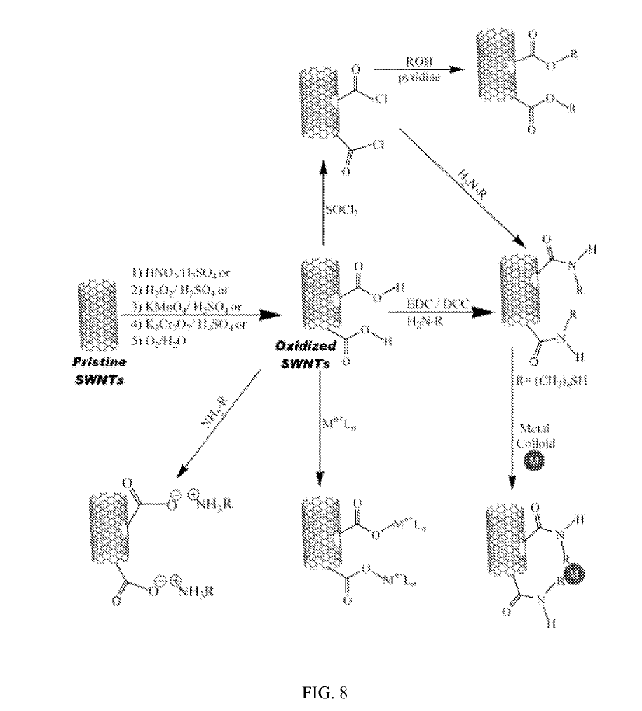

In alternative embodiments of the present invention, the active surface of the carbon film composite may be chemically modified to alter its chemical response spectrum. One skilled in the art can appreciate that there are a variety of known ways to modify carbon nanotubes for chemical selectivity. One non-limiting example includes using functional chemistry on the surface of carbon nanotubes. FIG. 8 is a scheme illustrating a known procedure for functionalizing carbon nanotubes. The technique demonstrated in FIG. 8 is called “covalent functionalization” and the same functional chemistry may be suitable for application to the active surface of the carbon film composite of the present invention. For example, this functionalization can be used to increase the solubility of carbon nanotubes and thus may be particularly suitable for use in liquid sensing applications. Alternatively, the functionalization demonstrated in FIG. 8 can be used to increase sensing affinity for particular simulated explosives and nerve agents. While these techniques were developed for use on individually grown carbon nanotubes, the present invention contemplates the use of such known functionalization schemes on carbon film composites of the present invention, as would be apparent to one skilled in the art for a particular application.

Another non-limiting example of known methods for chemically modifying carbon nanotubes includes the deposition of a thin polymer layer to the carbon nanotubes. For example, one skilled in the art would appreciate that several types of polymers have been developed for adding chemoselective properties to carbon nanotubes. These types of polymers would be equally suitable to be deposited onto the active surface of the carbon film composite of the present invention, as would be apparent to one skilled in the art for a particular application. Successful chemical modification of the active surface of the carbon film composite in these ways is expected since the active surface of the carbon film composite (whether or not it includes a network of carbon nanotubes) is 100% carbon, similar to that of pure carbon nanotubes.

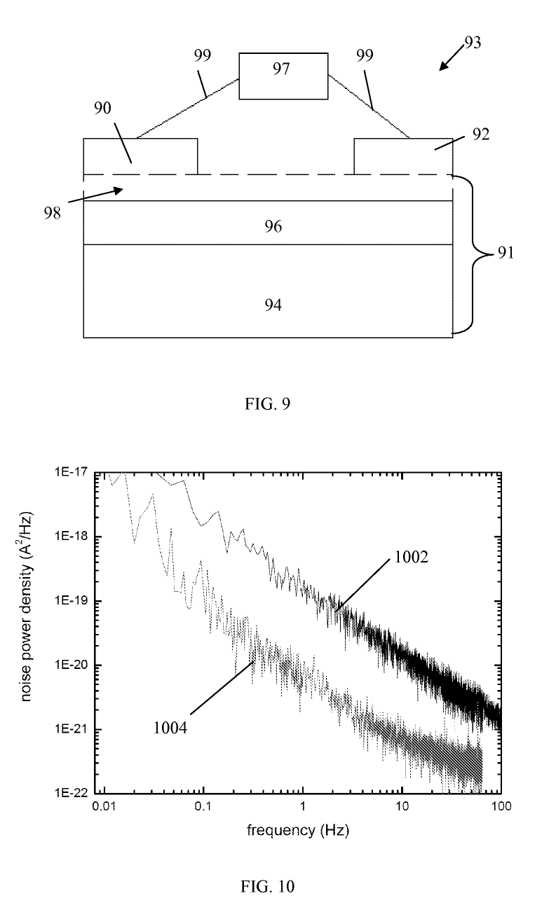

The carbon film composites of the present invention have been used as transducers, particularly for use in sensors for detecting applications. FIG. 9 is a schematic of a sensor 93 of the present invention including a carbon film composite 91 of the present invention as a transducer. The sensor 93 includes a first electrode 90 and a second electrode 92 that are in good electrical contact with an active surface of the carbon film composite 91 (i.e., either the optional carbon nanotubes 98 or the treated carbon film layer 96). The carbon film composite 91 includes a substrate 94, a carbon film layer 96 that has been treated according to the method described herein and optionally at least partial growth of carbon nanotubes 98 on the carbon film layer. One skilled in the art can appreciate that a variety of electrode materials and designs may be suitable in a sensor of the present invention. Non-limiting examples of electrode materials and arrangements were described in U.S. Patent Application Publication No. 2006/0249402, which is incorporated herein in its entirety.

A resistivity monitoring device 97, for example an ohmmeter, may be connected between the first and second electrodes 90/92 by leads 99. The resistivity monitoring device 97 may be a single instrument or may comprise a separate voltage source and ammeter. The resistivity of the carbon film composite 93 can be measured along with any changes in the resistivity in the presence of a target chemical. In alternative embodiments, capacitance of the carbon film composite may alternatively or additionally be measured to identify changes in the carbon film composite in the presence of a target chemical.

Similarly, the sensor 93 of the present invention may be incorporated into a sensor array of the present invention that includes a plurality of similar to different sensors. The sensor or sensor array of the present invention may be used to detect target chemicals in a variety of fluids, such as air, water, blood, hydraulic fluid, factory plumes, or any other suitable gas or liquid. The carbon film composite may be particularly adapted to detect biological or chemical target chemicals for use in biosensor or chemical detection applications.

The present invention is also directed to a method for sensing target chemicals using the carbon film composite of the present invention. The resistivity changes in a sensor or sensor array incorporating the carbon film composite may be recorded for a target chemical at various concentrations. A fingerprint response is then created using the recorded data such that the target chemical can then be identified in the presence of other chemicals.

While the invention has been particularly shown and described with reference to preferred embodiments thereof, it will be understood by those skilled in the art that they have been presented by way of example only, and not limitation, and various changes in form and details can be made therein without departing from the spirit and scope of the invention. Thus, the breadth and scope of the present invention should not be limited by any of the above-described exemplary embodiments, but should be defined only in accordance with the following claims and their equivalents. Additionally, all references cited herein, including issued U.S. patents, or any other references, are each entirely incorporated by reference herein, including all data, tables, figures, and text presented in the cited references. Also, it is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one of ordinary skill in the art.

The foregoing description of the specific embodiments will so fully reveal the general nature of the invention that others can, by applying knowledge within the skill of the art (including the contents of the references cited herein), readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein.

What is claimed as new and desired to be protected by Letters Patent of the United States is:

1. A method of manufacturing a carbon film composite, comprising:
providing a substrate;
depositing a carbon film layer onto the substrate;
depositing a catalyst onto the carbon film layer to form a catalyst-treated carbon film layer, wherein the catalyst is suitable for catalyzing the growth of carbon nanotubes; and
heating the catalyst-treated carbon film layer in the presence of a carbon-source gas in a substantially inert environment.

2. The method of claim 1, wherein the substrate is a dielectric material.

3. The method of claim 1, wherein the carbon film layer is deposited to a thickness of less than 100 angstroms.

4. The method of claim 1, wherein depositing a carbon film layer further comprises: depositing a carbon-containing polymer onto a substrate and carbonizing the carbon-containing polymer to form a carbon film layer.

5. The method of claim 4, wherein the carbon-containing polymer is a high-carbon content polymer.

6. The method of claim 4, wherein the carbon-containing polymer layer is carbonized at a temperature of about 500-1500° C.

7. The method of claim 4, wherein the carbon-containing polymer is carbonized in a substantially inert environment.

8. The method of claim 1, wherein the carbon film layer has a resistivity of about 1 k-Ω/sq or higher.

9. The method of claim 1, wherein the catalyst-coated carbon film layer is heated to a temperature of about 500-1500° C.

10. The method of claim 1, wherein the carbon-source gas is a hydrocarbon.

11. The method of claim 1, wherein carbon nanotubes are at least partially grown on the carbon film layer during heating.

12. The method of claim 1, further comprising:
chemically modifying the carbon film composite.

13. The method of claim 21, wherein chemically modifying the carbon film composite includes functionalizing the carbon film composite.

14. The method of claim 21, wherein chemically modifying the carbon film composite includes depositing a polymer layer onto the carbon film composite.

15. A composite material, comprising:
(a) a substrate; and
(b) a carbon film layer deposited onto the substrate, wherein the carbon film layer has an active surface that is electrically sensitive to the presence of target chemicals.

16. The composite material of claim 15, wherein the active surface comprising at least a partial growth of carbon nanotubes on the carbon film layer.

17. A chemical sensor, comprising:
a carbon film composite having a substrate and a carbon film layer applied to the substrate, wherein the carbon film layer is treated with a catalyst and heated in the presence of a carbon source gas in a substantially inert environment;
a first electrode in electrical contact with an active surface of the carbon film composite; and
a second electrode in electrical contact with the active surface of the carbon film composite; and
a resistivity monitoring device electrically connected to the first and second electrodes.

18. The chemical sensor of claim 17, wherein the sensor is insensitive to humidity changes in air.

19. A method of sensing a target chemical, comprising:
providing a chemical sensor incorporating a carbon film composite having a carbon film layer applied to a substrate that is treated with a catalyst and heated in the presence of a carbon source gas in a substantially inert environment;
exposing the carbon film composite to a target chemical; and
recording a change in resistivity across the carbon film composite for the target chemical.

20. The method of claim 19, further comprising a plurality of sensors in a sensor array.

21. The method of claim 19, further comprising exposing the carbon film composite to a particular target chemical at a variety of concentrations and developing a fingerprint response for the particular target chemical.

22. The method of claim 19, wherein the sample target chemical may be selected from the group consisting of toxic chemicals, explosives, nerve agents or biomolecules of interest.
